(19) United States
(12) Patent Application Publication
(10) Pub. No.: US 2022/0416897 A1
(43) Pub. Date: Dec. 29, 2022

(54) OPTICAL AMPLIFIER, RECEIVER, OPTICAL TRANSMISSION SYSTEM, AND OPTICAL AMPLIFIER DESIGN METHOD

(71) Applicant: Nippon Telegraph and Telephone Corporation, Tokyo (JP)

(72) Inventors: Kohei Saito, Musashino-shi, Tokyo (JP); Hiroki Kawahara, Musashino-shi, Tokyo (JP); Takeshi SEKI, Musashino-shi, Tokyo (JP); Hideki Maeda, Musashino-shi, Tokyo (JP)

(21) Appl. No.: 17/620,795

(22) PCT Filed: Jun. 21, 2019
(86) PCT No.: PCT/JP2019/024619

§ 371 Date: Dec. 20, 2021

(51) Int. Cl. H04B 10/291; H04B 10/293

(52) U.S. Cl. CPC H04B 10/2914; H04B 10/293; H01S 5/50

(57) ABSTRACT

An optical amplifier (21) configured to operate with saturated output power is coupled on the receive side with respect to a receiver (18) coupled to a transmitter (17) via an optical fiber (14). The saturated output power is represented as a saturation characteristic drawing a flat curve in which, as power (input optical power) of an optical signal (22i) inputted to the optical amplifier (21) increases in excess of a given level, the variation in power (output optical power) of an optical signal (22o) outputted from the optical amplifier (21) decreases. Consequently, information represented by the optical signal (22o) inputted from the optical amplifier (21) to the receiver (18) can be properly received.

### TECHNICAL FIELD

The present invention relates to an optical amplifier used in an optical transmission system in which transponder units each including a transmitter and a receiver for transmitting and receiving an optical signal are coupled at both ends of an optical transmission line. The present invention also relates to a receiver, the optical transmission system, and an optical amplifier design method.

### BACKGROUND ART

FIG. 16 is a block diagram illustrating a configuration of a known optical transmission system 10. The optical transmission system 10 involves a plurality of units provided separately at two distant locations. At one of the distant locations, the optical transmission system 10 includes a plurality of transponder units 11a to 11n, an optical combiner and splitter unit 12a, and an optical amplification unit 13a. At the other of the distant locations, the optical transmission system 10 includes an optical amplification unit 13b, an optical combiner and splitter unit 12b, and a plurality of transponder units 16a to 16n. The optical transmission system 10 includes an optical fiber 14 as an optical transmission line connecting the optical amplification unit 13a at the one location and the optical amplification unit 13b at the other location and a plurality of optical cross-connect units 15a and 15n inserted in the optical fiber 14.

The transponder units 11a to 11n and 16a to 16n each include a transmitter 17 and a receiver 18 as illustrated by using the transponder units 11a and 16a. While the optical transmission system 10 can perform bidirectional communication, the following description is about the case in which the transmitters 17 of the transponder units 11a to 11n on the left side of the drawing (transmit side) transmits optical signals to the receivers 18 of the transponder units 16a to 16n on the right side (receive side).

The optical transmission system 10 employs wavelength division multiplexing (WDM) technology. In the optical transmission system 10, the optical combiner and splitter unit 12a combines optical signals from the transmitters 17 of the transponder units 11a to 11n into a multiplexed WDM signal, and the optical amplification unit 13a amplifies the WDM signal and transmits the amplified WDM signal to the optical fiber 14. In the optical fiber 14, the optical cross-connect units 15a and 15n subject the optical signal to add/drop processing. After the optical signal is transmitted as described above through the optical fiber 14, the optical amplification unit 13b on the receive side amplifies the optical signal, the optical combiner and splitter unit 12b splits the optical signal, and the receivers 18 of the transponder units 16a to 16n receive the split optical signals. The transponder units 16a to 16n then transmit the received optical signals to communication terminals not illustrated in the drawing. An example of this kind of optical transmission system is a technology described in Patent Literature 1.

### CITATION LIST

### Patent Literature

Patent Literature 1: Japanese Patent Laid-Open No. 2006-292893

### SUMMARY OF THE INVENTION

### Technical Problem

In the optical transmission system 10, as described in Patent Literature 1, when a foreign object, such as a maintenance staff, contacts the optical fiber (optical fiber touch), the bend loss of the optical fiber 14 is changed and the power of optical signal in the optical fiber 14 is accordingly changed, which causes instantaneous loss variation in which the quality of optical signal is degraded due to instantaneous loss in the order of milliseconds or of about several dB. There is a problem in which, when the instantaneous loss variation exceeding a given level occurs in an optical signal inputted from the optical fiber 14 to the receiver 18, the receiver 18 cannot properly receive information.

The present invention has been made in consideration of the above circumstances, and an object thereof is to provide an optical amplifier, a receiver, an optical transmission system, and an optical amplifier design method in which instantaneous loss variation due to optical fiber touch is suppressed so that the receiver can properly receive information.

### Means for Solving the Problem

To address the problem described above, an optical amplifier of the present invention is characterized in that the optical amplifier coupled on the receive side with respect to a receiver for receiving an optical signal from a transmitter for optical signal through an optical transmission line is configured to operate with saturated output power.

### Effects of the Invention

By the present invention, the optical amplifier can suppress instantaneous loss variation due to optical fiber touch, and as a result, the receiver can properly receive information.

### BRIEF DESCRIPTION OF DRAWINGS

FIG. 1 is a block diagram of a configuration of an optical transmission system using an optical amplifier configured to operate with saturated output power according to a first embodiment of the present invention.

FIG. 2 is a block diagram illustrating a detailed configuration of the optical transmission system according to the first embodiment of the present invention.

FIG. 3 illustrates input-output characteristics in the case in which the optical amplifier with saturated output power is constituted by an erbium doped optical fiber amplifier (EDFA).

FIG. 4 is a block diagram illustrating a configuration of an optical amplifier design device for designing the optical amplifier configured to operate with saturated output power.

FIG. 5 is a flowchart for explaining a process in which the optical amplifier design device implements a method of designing the optical amplifier configured to operate with saturated output power.

FIG. 6 is a block diagram illustrating a configuration of an optical transmission system according to a first application example of the first embodiment of the present invention.

FIG. 7 illustrates characteristics of output optical power (Output Power) (dBm) indicated by the vertical axis to pump current (Pump Current) (mA) of the optical amplifier configured to operate with saturated output power indicated by the horizontal axis.

FIG. 8 is a block diagram illustrating a configuration of an optical transmission system according to a second embodiment of the present invention.

FIG. 9 is a block diagram illustrating a configuration of a normalization device.

FIG. 10 is a block diagram illustrating a hardware configuration of the normalization device.

FIG. 11 is a block diagram illustrating a smoothing processing circuit for digital signal in a digital signal processing device.

FIG. 12 illustrates data 46 obtained by smoothing up and down fluctuations of original data 45 by performing moving average processing with the use of the smoothing processing circuit.

FIG. 13 is a flowchart for explaining an operation of normalization processing performed by the normalization device.

FIG. 14 illustrates an example of a method of adjusting parameters N and M with the use of a parameter adjustment unit of the normalization device.

FIG. 15 is a block diagram illustrating a configuration of an optical transmission system according to a third embodiment.

FIG. 16 is a block diagram illustrating a configuration of a known optical transmission system.

### DESCRIPTION OF EMBODIMENTS

Hereinafter, embodiments of the present invention will be described with reference to the drawings. In all the drawings of this specification, constituent elements corresponding to each other with regard to function are assigned the same reference character, and descriptions thereof are omitted as appropriate.

<Configuration of First Embodiment>

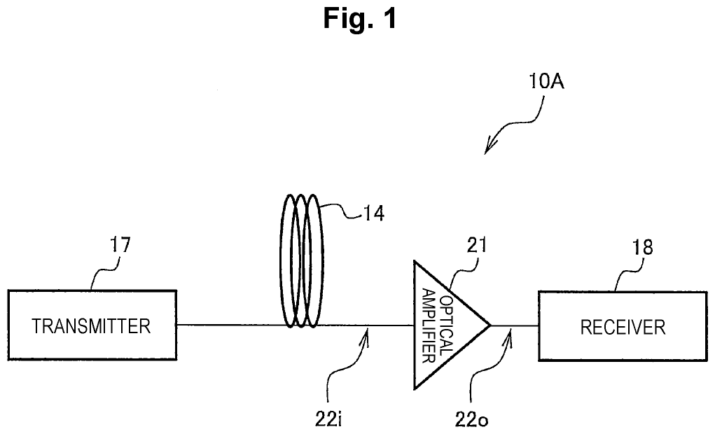

FIG. 1 is a block diagram of a configuration of an optical transmission system using an optical amplifier configured to operate with saturated output power according to a first embodiment of the present invention. An optical transmission system 10A illustrated in FIG. 1 is characterized in that the optical amplifier 21 configured to operate with saturated output power is coupled on the receive side (input side) with respect to the receiver 18 coupled to the transmitter 17 by using the optical fiber (optical transmission line) 14.

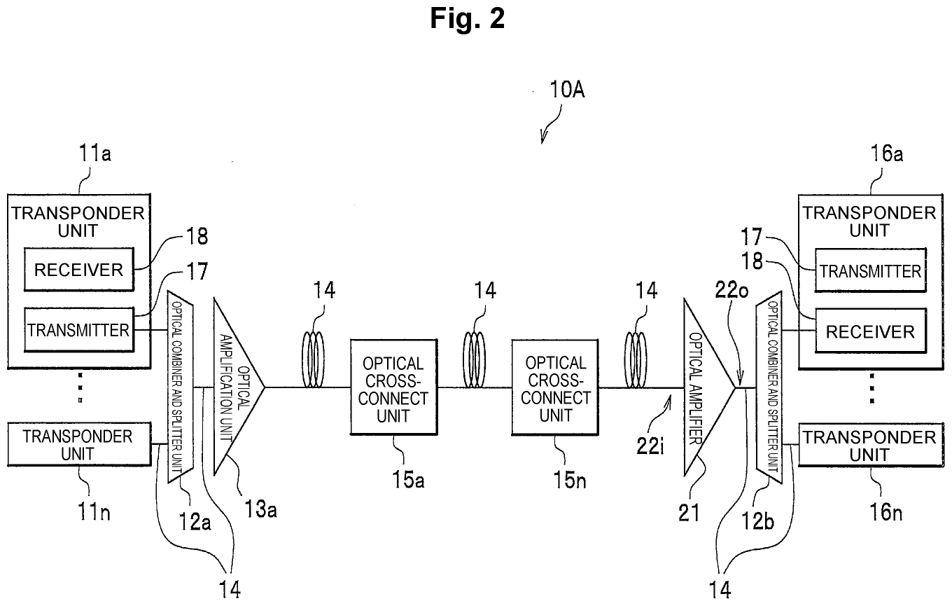

In FIG. 2 more specifically illustrating the configuration of the optical transmission system 10A, the optical amplifier 21 configured to operate with saturated output power is coupled on the receive side with respect to the receivers 18 of the transponder units 16a to 16n via the optical combiner and splitter unit 12b. Alternatively, the optical amplifier 21 may be coupled between the receive side with respect to the receivers 18 of the transponder units 16a to 16n and the optical combiner and splitter unit 12b.

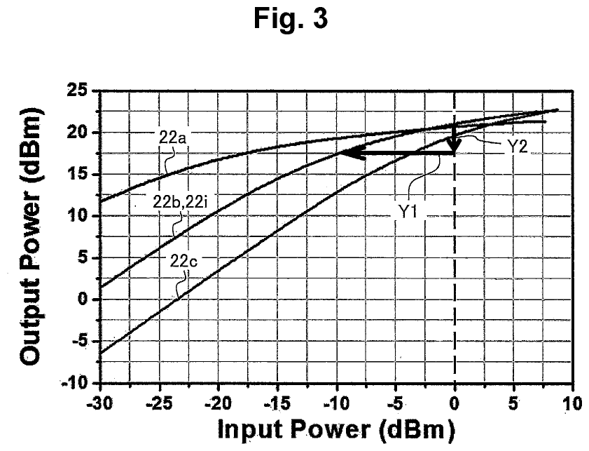

The saturated output power of the optical amplifier 21 is represented as a saturation characteristic in which, as power (input optical power) of an optical signal 22i inputted to the optical amplifier 21 increases in excess of a given level, the variation in power (output optical power) of an optical signal 22o outputted from the optical amplifier 21 decreases. FIG. 3 illustrates an example of the saturation characteristic.

FIG. 3 illustrates input-output characteristics in the case in which the optical amplifier 21 is constituted by an erbium doped optical fiber amplifier (EDFA). In FIG. 3, the horizontal axis indicates input optical power (Input Power) (dBm) and the vertical axis indicates output optical power (Output Power) (dBm). As for the input-output characteristic (amplification characteristic), a curved line 22a represents an optical signal at a wavelength of 1530 nm, a curved line 22b represents an optical signal at a wavelength of 1550 nm, and a curved line 22c represents an optical signal at a wavelength of 1565 nm.

When the input optical power is in the range of −30 to −5 dBm, the optical signal 22a indicates a characteristic drawing a gentle curve in which the output optical power gradually increases from about 12 to 20 dBm. After the input optical power exceeds −5 dBm, the optical signal 22a indicates a saturated output power characteristic (saturation characteristic) drawing a flat curve in which the output optical power hardly increases from about 20 dBm.

When the input optical power is in the range of −30 to 0 dBm, the optical signal 22b indicates a characteristic drawing a curve that is steeper than the curve of the optical signal 22a and in which the output optical power gradually increases from 2 to 22 dBm. After the input optical power exceeds 0 dBm, the optical signal 22b indicates a saturation characteristic drawing a flat curve in which the output optical power hardly increases from about 22 dBm.

When the input optical power is in the range of −30 to 5 dBm, the optical signal 22c indicates a characteristic drawing a curve that is steeper than the curve of the optical signal 22b and in which the output optical power gradually increases from −7 to 23 dBm. After the input optical power exceeds 5 dBm, the optical signal 22c indicates a saturation characteristic drawing a flat curve in which the output optical power hardly increases from about 23 dBm.

As described above, in the optical amplifier 21 with saturated output power illustrated as a flat curve representing the ratio of output power to input power, when the variation in the input optical power is relatively large, the variation in the output optical power is small. Hence, when an instantaneous loss variation due to optical fiber touch relatively greatly changes the input optical power to the optical amplifier 21, operating the optical amplifier 21 with saturated output power can suppress (or reduce) the variation in output optical power.

Since the optical amplifier 21 configured to operate with saturated output power can reduce the variation in output optical power resulting from the variation in the input optical power due to instantaneous loss variation so as to suppress the variation in output optical power as described above, it is possible to properly receive information represented by the optical signal 22o (FIG. 1) inputted from the optical amplifier 21 to the receiver 18.

<Optical Amplifier Design Method>

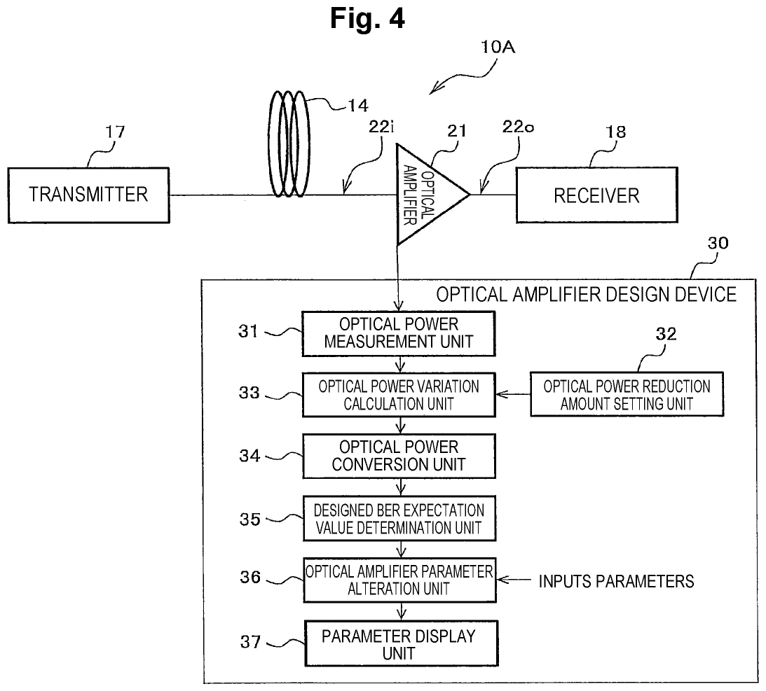

Next, an optical amplifier design device 30 illustrated in FIG. 4 described above designs the optical amplifier 21 configured to operate with saturated output power described above. The optical amplifier design device 30 includes an optical power measurement unit 31, an optical power reduction amount setting unit (configuration unit) 32, an optical power variation calculation unit 33, an optical power conversion unit 34, a designed bit error rate (BER) expectation value determination unit 35, an optical amplifier parameter alteration unit 36, and a parameter display unit 37.

The optical power measurement unit 31 of the optical amplifier design device 30 is coupled to the optical amplifier 21 configured to operate with saturated output power on the receive side with respect to the receiver 18. The optical power measurement unit 31 measures the input optical power of the optical signal 22i inputted to the optical amplifier 21.

An estimated reduction amount (dB) of input optical power due to instantaneous loss variation caused by optical fiber touch is set in the optical power reduction amount setting unit 32. This configuration is based on the estimation by a designer in accordance with, for example, statistics. The optical power variation calculation unit 33 calculates the variation amount of output optical power corresponding to the estimated reduction amount.

The optical power conversion unit 34 converts the variation amount of output optical power calculated as described above into a signal quality BER (Bit Error Rate) of the receiver 18. The designed BER expectation value determination unit 35 determines whether the signal quality BER obtained by the conversion is equal to or less than the designed BER expectation value (BER expectation value) that is predetermined. The designed BER expectation value is set at a value including a safety margin so that no error occurs (normal reception) when the signal quality is degraded.

The optical amplifier parameter alteration unit (also shortly referred to as the alteration unit) 36 alters parameters of the optical amplifier 21 when the optical power conversion unit 34 determines that the signal quality BER obtained by conversion is neither equal to nor less than the designed BER expectation value, in other words, when the signal quality BER is greater than the designed BER expectation value. Here, the optical amplifier 21 is an EDFA. The change of parameters is carried out by the designer inputting, for example, the power of pump light, the material of erbium doped optical fiber (EDF), and the length of EDF into the alteration unit 36. For example, characteristics of the optical amplifier 21 are changed by changing the percentage of a rare-earth element.

The parameter display unit 37 displays the parameters inputted to the alteration unit 36. The designer changes the parameters while viewing the displayed parameters.

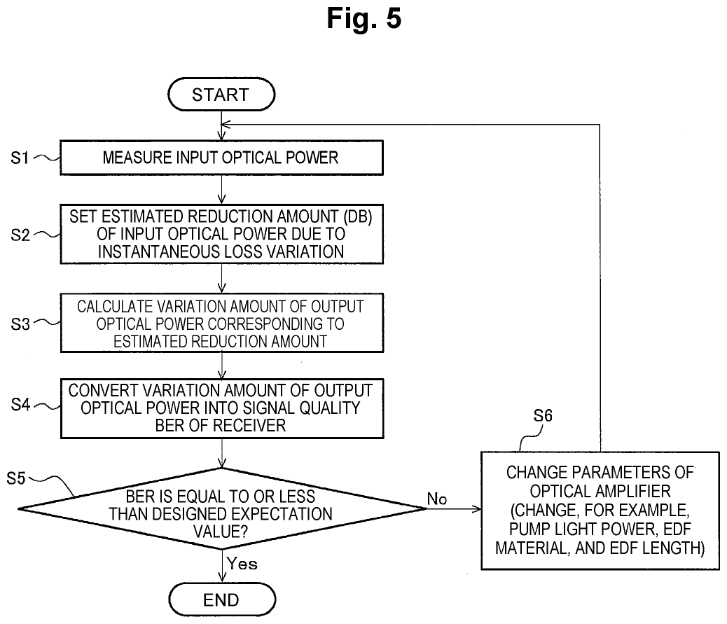

A process of the method of designing the optical amplifier 21 configured to operate with saturated output power with the use of the optical amplifier design device 30 will be described with reference to a flowchart illustrated in FIG. 5.

In step S1, the optical power measurement unit 31 measures the input optical power of the optical signal 22i inputted to the optical amplifier 21. It is assumed that the optical signal 22i is identical to the optical signal 22b indicated in FIG. 3, in which the wavelength is 1550 nm and the input optical power in normal operation is 0 dBm. In this case, the input optical power measured by the optical power measurement unit 31 is 0 dBm.

In step S2, for example, the designer sets an estimated reduction amount (dB) of input optical power due to instantaneous loss variation in the optical power reduction amount setting unit 32. For example, when the estimated reduction amount is estimated as 10 dB, the input optical power measured in step S1 is −10 dB, which is obtained by subtracting 10 dB from 0 dBm as indicated by an arrow Y1 in FIG. 3.

In step S3, a variation amount of output optical power corresponding to the estimated reduction amount, for example −10 dB, is calculated as described below. In this case, when the input optical power is 0 dB, the output optical power is 20.7 dB as indicated by the intersection point of 0 dB of the input optical power and the characteristic curved line 22b of the optical signal 22i as illustrated in FIG. 3. Since the input optical power including the estimated reduction amount is −10 dB as described above, the output optical power is 17.5 dB as indicated by the intersection point of −10 dB and the curved line 22b.

Accordingly, the variation amount of output optical power is 3.2 dB, which is obtained by subtracting 17.5 dB from 20.7 dB as indicated by an arrow Y2. As described above, the optical amplifier 21 with saturated output power can reduce the variation amount from 10 dB of input optical power resulting from instantaneous loss variation to 3.2 dB of output optical power.

Next, in step S4, the optical power conversion unit 34 converts 3.2 db of the variation amount of output optical power calculated as described above into a signal quality BER (Bit Error Rate) of the receiver 18. The optical power conversion unit 34 measures the BER in the state in which the variation amount of output optical power is reduced to 3.2 dB. As a result, it is assumed that the signal quality BER is converted into, for example, a value decreased by 10%.

In step S5, the designed BER expectation value determination unit 35 determines whether the signal quality BER obtained by the conversion is equal to or less than the designed BER expectation value predetermined. When the signal quality BER is, for example, decreased by 10%, it is determined whether the signal quality BER is equal to or less than 10⁻¹³ of the designed BER expectation value. As a result, when the result indicates that the signal quality BER is equal to or less than the designed BER expectation value (Yes), the design process ends because the optical amplifier 21 reaches a target level.

Conversely, if the determination result indicates that the signal quality BER is neither equal to nor less than the designed BER expectation value (No), the process proceeds to step S6. In step S6, the designer changes parameters of the optical amplifier 21 and inputs the parameters into the alteration unit 36. Since the optical amplifier 21 is an EDFA in this example, the designer changes, for example, the power of pump light, the material of EDF, and the length of EDF by inputting the parameters into the alteration unit 36. The parameter display unit 37 displays the changed parameters.

Subsequently, the optical amplifier 21 is produced in accordance with the changes, and the processing operations in steps S2 to S5 are performed. When the result in step S5 is Yes, the process ends. When the result in step S5 is No, the processing operation in step S6 is repeated until the result in step S5 indicates Yes. It should be noted that the optical amplifier 21 may be implemented on software by using, for example, a simulator not illustrated in the drawing, and in this state, the processing operations in steps S1 to S6 may be performed.

According to the first embodiment, the optical transmission system 10 is formed by connecting the transmitter 17 for transmitting the optical signal 22i and the receiver 18 for receiving the optical signal 22i with the use of the optical fiber 14 as an optical transmission line. In the optical transmission system 10, the optical amplifier 21 coupled on the receive side with respect to the receiver 18 is configured to operate with saturated output power.

With this configuration, when the optical amplifier 21 operates with saturated output power, the ratio of output power to input power draws a flat curve; this means that when the variation in input optical power is relatively large, the variation in output optical power is small. As a result, when an instantaneous loss variation due to optical fiber touch changes the input optical power to the optical amplifier 21, the variation in output optical power is suppressed and reduced to a smaller amount. Due to this reduction, information represented by the optical signal 22o inputted from the optical amplifier 21 to the receiver 18 can be properly received.

The optical amplifier 21 configured to operate with saturated output power, which can achieve such effects, is designed by following the order of the processing operations in steps S1 to S6 described above. By using this design procedure, the optical amplifier 21 configured to operate with saturated output power can be produced to reduce instantaneous loss variation occurred in the optical signal 22i transmitted through the optical fiber 14, and consequently, the receiver 18 can obtain correct information.

<First Application Example of First Embodiment>

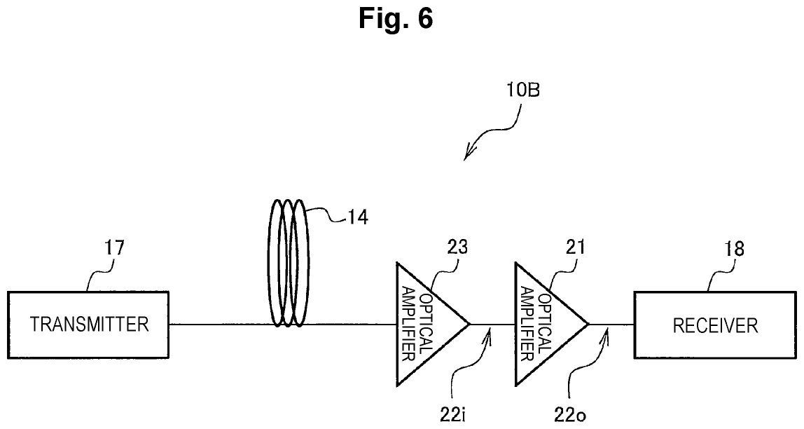

FIG. 6 is a block diagram illustrating a configuration of an optical transmission system according to a first application example of the first embodiment of the present invention. An optical transmission system 10B of the first application example illustrated in FIG. 6 is characterized in that an input-power-adjusting optical amplifier 23 is coupled on the input side with respect to the optical amplifier 21 configured to operate with saturated output power. The input-power-adjusting optical amplifier 23 is constituted by, for example, an EDFA and configured to adjust input power to the optical amplifier 21.

Specifically, the input-power-adjusting optical amplifier 23 previously increases the power of the optical signal 22i to be outputted by the optical amplifier 23 and inputted to the optical amplifier 21 in the subsequent stage, and as a result, the optical amplifier 21 operates in an amplification area of a flatter curve (FIG. 3), resulting in suppressed and further reduced instantaneous loss variation.

<Second Application Example of First Embodiment>

Next, a second application example of the first embodiment of the present invention will be described. The second application example is characterized in that the power of pump light is changed by changing the amount of pump current to adjust the saturated output power of the optical amplifier 21 illustrated in FIG. 1 so that the variation in output optical power is further reduced. It is preferable that an EDFA be used as the optical amplifier 21.

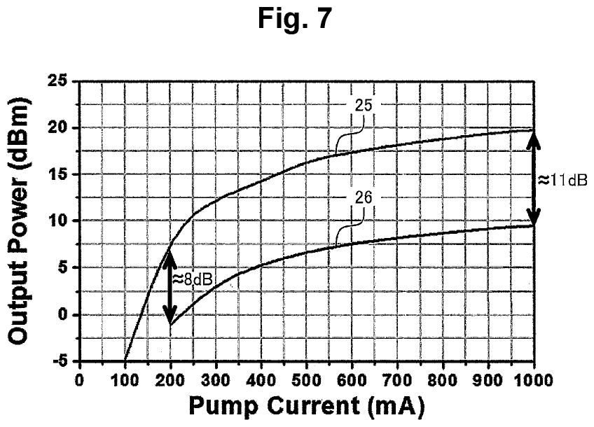

FIG. 7 illustrates characteristics of output optical power (Output Power) (dBm) indicated by the vertical axis to pump current (Pump Current) (mA) of the optical amplifier 21 indicated by the horizontal axis. In FIG. 7, a curved line 25 indicates a characteristic in the case in which the input optical power of optical signal is −20 dBm, and a curved line 26 indicates a characteristic in the case in which the input optical power of optical signal is 0 dBm.

In the case in which the pump current is 1000 mA, when the input optical power changes from −20 dBm indicated by the curved line 25 to 0 dBm indicated by the curved line 26, the variation in output optical power is approximately 11 dB.

In the case in which the pump current is 200 mA, when the input optical power changes from −20 dBm indicated by the curved line 25 to 0 dBm indicated by the curved line 26, the variation in output optical power is approximately 8 dB.

As described above, when the optical amplifier 21 operates with a pump current of 200 mA, the variation in output optical power is as small as approximately 8 dB in comparison to approximately 11 dB in the case of a pump current of 1000 mA, such that instantaneous loss variation can be reduced. Thus, it can be understood that, as the pump current of the optical amplifier 21 decreases, the reduction in instantaneous loss variation increases.

<Third Application Example of First Embodiment>

Next, a third application example of the first embodiment of the present invention will be described. The third application example is characterized in that a semiconductor optical amplifier (SOA) is used as the optical amplifier 21 configured to operate with saturated output power illustrated in FIG. 1.

The SOA is structured as a laser diode without feedback to input and output ports; more specifically, the edge surface (cleaved surface) of the semiconductor laser does not reflect laser beams. The SOA is capable of amplification with a wide range of wavelength. Furthermore, the SOA needs components less than the EDFA. Using the SOA can achieve downsizing of amplifier and lower power consumption.

Since the saturated output power of SOA is smaller than the saturated output power of EDFA, the SOA indicates a characteristic in which the output optical power draws a flat curve in the area with small input optical power. This means that using the SOA as the optical amplifier 21 can reduce instantaneous loss variation with the use of the characteristic in which the output optical power draws a flat curve when the input optical power is relatively small (refer to FIG. 3).

In the configuration in which the input-power-adjusting optical amplifier 23 is coupled on the input side with respect to the optical amplifier 21 configured to operate with saturated output power as illustrated in FIG. 6, one of the amplifiers, for example the optical amplifier 21, is implemented as a SOA, and the other of the amplifiers, for example the optical amplifier 23, is implemented as an EDFA; or the same applies in reverse. Also with this configuration, it is possible to reduce instantaneous loss variation with the use of the characteristic in which the output optical power draws a flat curve when the input optical power of the SOA is relatively small.

Additionally, to adjust the saturated output power of the SOA, the variation in output optical power can be further reduced by decreasing the current injected corresponding to the pump current. This means that the SOA also operates such that, as the injected current decreases, instantaneous loss variation decreases.

<Configuration of Second Embodiment>

FIG. 8 is a block diagram illustrating a configuration of an optical transmission system according to a second embodiment of the present invention. An optical transmission system 10C illustrated in FIG. 8 is constructed by providing at distant locations the transmitter 17 and a receiver 18A connected to each other by the optical fiber 14 and coupling the optical amplification unit 13b on the receive side of the optical fiber 14 with respect to the receiver 18A.

The receiver 18A includes an optical/electrical (O/E) conversion device 18b, an analog/digital (A/D) conversion device 18c, a digital signal processing device 18d, and an information recognition device 18e. The A/D conversion device 18c includes a sampling device 18f and also includes a normalization device 18g that characterizes the present embodiment.

The O/E conversion device 18b receives an optical signal transmitted by the transmitter 17, communicated through the optical fiber 14, and then amplified by the optical amplification unit 13b and converts the optical signal into an analog electrical signal by demodulating the optical signal. The A/D conversion device 18c converts the electrical signal into a digital signal. The digital signal processing device 18d performs digital signal processing operations such as polarization split of digital signal, compensation for polarization/wavelength dispersion of digital signal, compensation for waveform distortion of digital signal, compensation for frequency/phase offset of digital signal. The information recognition device 18e recognizes information (information represented as “0” or “1”) consisting of an array “0, 1, . . . ” in accordance with the signal having been subjected to the processing operations for digital signal.

The sampling device 18f of the A/D conversion device 18c performs sampling by sectioning the electrical signal converted by the O/E conversion device 18b at fixed time intervals and read values from the sectioned electrical signal. This means that the sampling device 18f converts received optical power into samples.

The normalization device 18g monitors received optical power converted by the sampling device 18f into samples of fixed cycle periods and normalizes the received optical power by using the average power determined as “1” so as to convert the received optical power into the form easily usable in the subsequent stage. During the normalization processing, the normalization device 18g controls the cycle period for monitoring in accordance with information represented as “0, 1, . . . ” fed back by the information recognition device 18e, such that the effect on the digital signal processing device 18d due to instantaneous loss variation is reduced.

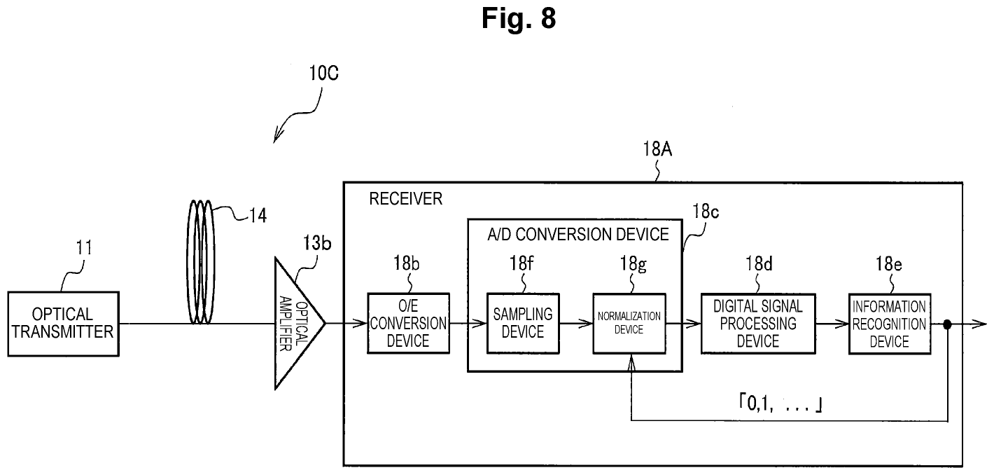

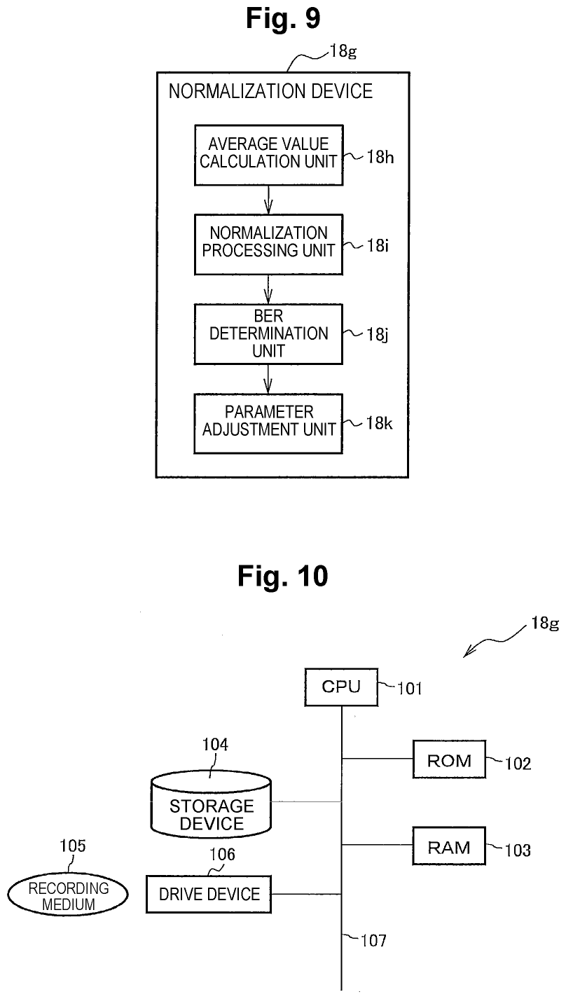

As illustrated in FIG. 9, the normalization device 18g includes an average value calculation unit 18h, a normalization processing unit 18i, a BER determination unit 18j, and a parameter adjustment unit 18k.

The average value calculation unit 18h calculates the average value of received optical power converted into samples by the sampling device 18f. By this calculation, an average value of received optical power is calculated in accordance with the latest sample to the Nth past sample. N is a parameter corresponding to the length of the cycle period used to convert an electrical signal of received optical power into samples. This parameter can be adjusted as appropriate.

The normalization processing unit 18i normalizes samples to “1” by dividing each sample by the average value described above. The samples for normalization are M most recent samples in chronological order inputted into the normalization device 18g. M is a parameter adjustable as appropriate.

The BER determination unit 18j determines, when an instantaneous loss variation occurs, whether the BER calculated in accordance with values obtained by normalizing the information “0, 1, . . . ” recognized by the information recognition device 18e with the use of the parameters N and M described above indicates a smallest value. The BER determination unit 18j may determine whether the BER is equal to or less than a predetermined threshold. The parameters N and M are determined to be normalization parameters most suitable for the amount of instantaneous loss variation and the form of variation, such as triangle, pulse, or spike during the normalization processing.

When the BER determination unit 18j determines that the BER does not indicate a smallest value, the parameter adjustment unit 18k adjusts the parameters N and M. After this adjustment, the average value calculation unit 18h calculates again an average value of the received optical power converted into samples, and after the calculation, the normalization processing unit 18i, the BER determination unit 18j, and the parameter adjustment unit 18k repeat the same processing operations.

<Hardware Configuration of Normalization Device>

The normalization device 18g includes a central processing unit (CPU) 101, a read only memory (ROM) 102, a random access memory (RAM) 103, a storage device (for example, a hard disk drive (HDD)) 104, and a recording medium 105 as illustrated in FIG. 10. The normalization device 18g has a typical configuration in which the components 101 to 104 are coupled to a bus 107, and the recording medium 105 is coupled to the bus 107 via a drive device 106. The recording medium 105 is, for example, an optical storage medium, such as a digital versatile disc (DVD) or phase change rewritable disk (PD), a magneto-optical storage medium, such as a magneto optical disk (MO), a magnetic recording medium, a conductive recording tape medium, or a semiconductor memory.

With this configuration, when the recording medium 105 retaining a program and the like is set in the drive device 106, the drive device 106 loads onto the RAM 103 the program retained in the recording medium 105. The CPU 101 executes the program for target processing operations loaded on the RAM 103. By executing the program, the CPU 101 controls the functions of the normalization device 18g.

The program may be loaded onto the RAM 103 from a computer through a network. Alternatively, the CPU 101 may execute a program retained in the ROM 102 to implement the target processing operations. The RAM 103 can also store, for example, necessary data and files in addition to the program. Alternatively, the normalization device 18g may implement the target processing operations by using a semiconductor integrated circuit such as a digital signal processor (DSP) or application specific integrated circuit (ASIC).

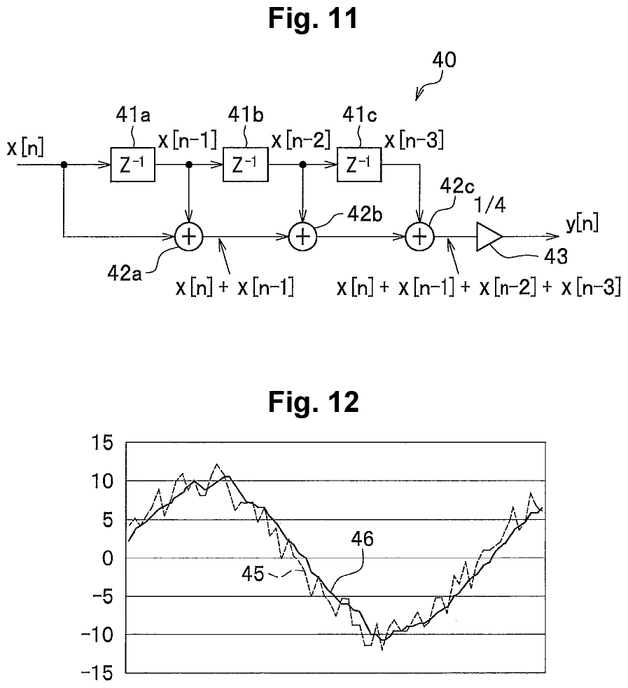

When the BER is minimized as described above, the digital signal processing device 18d smooths the digital signal corresponding to the received optical power outputted by the normalization device 18g. The digital signal processing device 18d includes a smoothing processing circuit 40 for digital signal illustrated in FIG. 11.

The smoothing processing circuit 40 processes data of the latest sample to the fourth past sample (N=4) described above. The smoothing processing circuit 40 includes delayers (Z⁻¹) 41a, 41b, and 41c, adders 42a, 42b, and 42c, and a divider 43 for division by 4.

The delayers 41a to 41c output inputs delayed by one sample time. When it is assumed that the present value of a digital signal is x[n], the value of a first sample from the present on the output side with respect to the delayer 41a is x[n−1]; the value of a second sample from the present on the output side of the delayer 41b is x[n−2]; the value of a third sample from the present on the output side of the delayer 41c is x[n−3].

The first adder 42a adds x[n] of the present value and x[n−1] of the value delayed by one sample and accordingly outputs x[n]+x[n−1]. Successively performing addition by using the second adder 42b and then the third adder 42c as described above results in x[n]+x[n−1]+x[n−2]+x[n−3]. The divider 43 averages the result by dividing the result by 4, such that moving average processing is performed.

With such moving average processing, data 46 can be obtained by smoothing up and down fluctuations of original data (digital signal) 45 as illustrated in FIG. 12. More specifically, the original data 45 including high frequency components slightly fluctuates up and down, and thus, by suppressing and smoothing fluctuations with moving average processing, the data 46 including only low frequency components can be obtained. From the data 46, the information recognition device 18e can accurately recognize the information of “0, 1, . . . ”.

<Operation of Normalization Processing>

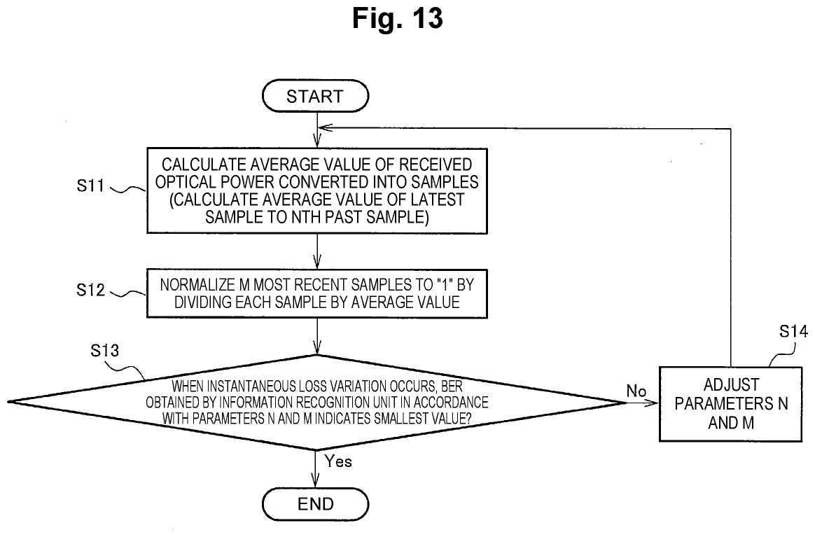

Next, normalization processing performed by the normalization device 18g will be specifically described with reference to a flowchart illustrated in FIG. 13.

In step S11, the normalization device 18g calculates the average value of received optical power converted into samples by the sampling device 18f. By this calculation, for example, it is assumed that an average value “100” is obtained in accordance with the present sample to the 100th past sample (N=100) when the modulation speed is 10 Gbuad and the sampling speed is 20 Gbaud.

In step S12, the normalization processing unit 18i normalizes samples to “1” by dividing each sample by the average value “100” described above. The samples for normalization are M (M=100) most recent samples in chronological order inputted into the normalization device 18g. In this case, the received optical power after normalization indicates “1”.

In step S13, when an instantaneous loss variation occurs, the BER determination unit 18j determines whether the BER obtained and fed back by the information recognition device 18e in accordance with the parameters N and M indicates a smallest value. When the determination result indicates that the BER is a smallest BER (Yes), the normalization processing ends because the instantaneous loss variation is reduced to the smallest level.

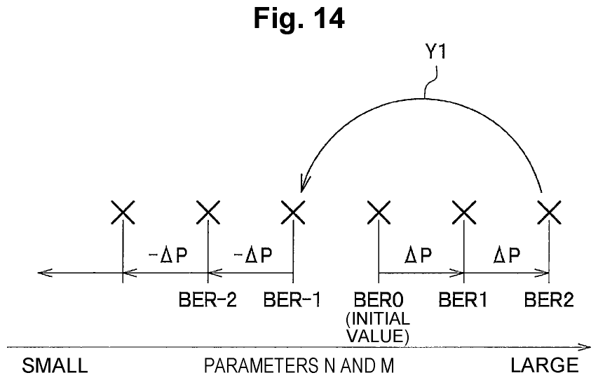

By contrast, when the determination result indicates that the BER is not a smallest BER (No), the parameter adjustment unit (also shortly referred to as the adjustment unit) 18k adjusts the parameters N and M in step S14. After this adjustment, the process returns to step S11 described above. Here, an example of the adjustment method will be described with reference to FIG. 14.

As illustrated in FIG. 14, the adjustment unit 18k determines as an initial value BER0 a BER having been used for determination by the BER determination unit 18j in accordance with “0, 1, . . . ” that have been fed back. The adjustment unit 18k changes both or one of the parameters N and M so as to increase the BER from the initial value BER0 by a fixed value ΔP. By changing the parameters N and M as described above, a changed value of BER is fed back.

The adjustment unit 18k records fed back BER1 in a storage unit (not illustrated in the drawing) when the BER is increased by ΔP for the first time, and also BER2 fed back when the BER is increased by ΔP for the second time. The adjustment unit 18k determines that the BER is degraded when BER1 and BER2 recorded two times successively increase.

In response to this determination, the adjustment unit 18k adjusts the parameters N and M to shift the BER to decrease the BER two times by a fixed value −ΔP in the direction opposite to the direction in which the BER have increased two times as indicated by an arrow Y1. According to this shift, the adjustment unit 18k records BER-1 fed back at the first time and BER-2 fed back at the second time in the storage unit.

When BER-1 and BER-2 recorded two times at the time of BER shift successively decrease, the adjustment unit 18k determines that the BER is slightly reduced, in other words, the instantaneous loss variation is slightly reduced. After this determination, the adjustment unit 18k adjusts the parameters N and M to decrease the fed back BER to a smallest BER. When the BER indicates a smallest value, the adjustment unit 18k determines and sets the corresponding parameters N and M. As such, it is possible to minimize instantaneous loss variation.

Alternatively, a particular combination of the parameters N and M corresponding to a smallest BER may be selected from a plurality of different combinations (for example, 100 combinations) of the parameters N and M in accordance with the BER calculated by using each combination.

The processing in step S13 is to detect only the BER, but the detection of the optical signal to noise ratio (OSNR) cannot be achieved. This means that the OSNR when an instantaneous loss variation occurs cannot be compensated. The processing is to increase the amplitude of sampling data, and as a result, noise components are enlarged, which does not change the OSNR.

The digital signal processing device 18d, which performs digital coherent signal processing for the receiver 18, also performs processing for preventing instantaneous loss variation from worsening designed performance. In adaptive equalization processing after this processing, transmission distortion is compensated by using an algorithm such as constant modulus algorithm (CMA)=quadrature phase shift keying (QPSK). However, since the CMA targets “1” for processing, for example, when data of “0.8” is temporarily inputted due to instantaneous loss variation, the signal quality is degraded. Hence, the processing for preventing instantaneous loss variation from worsening designed performance is performed.

### Third Embodiment

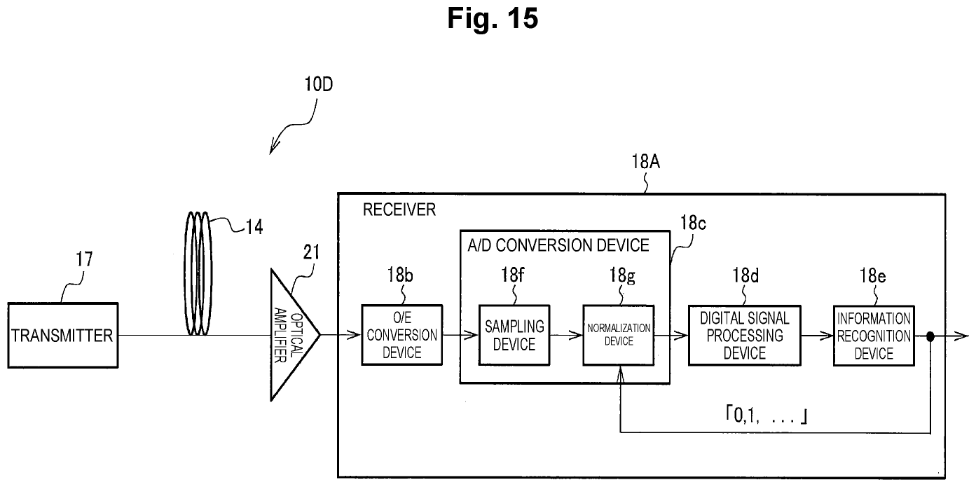

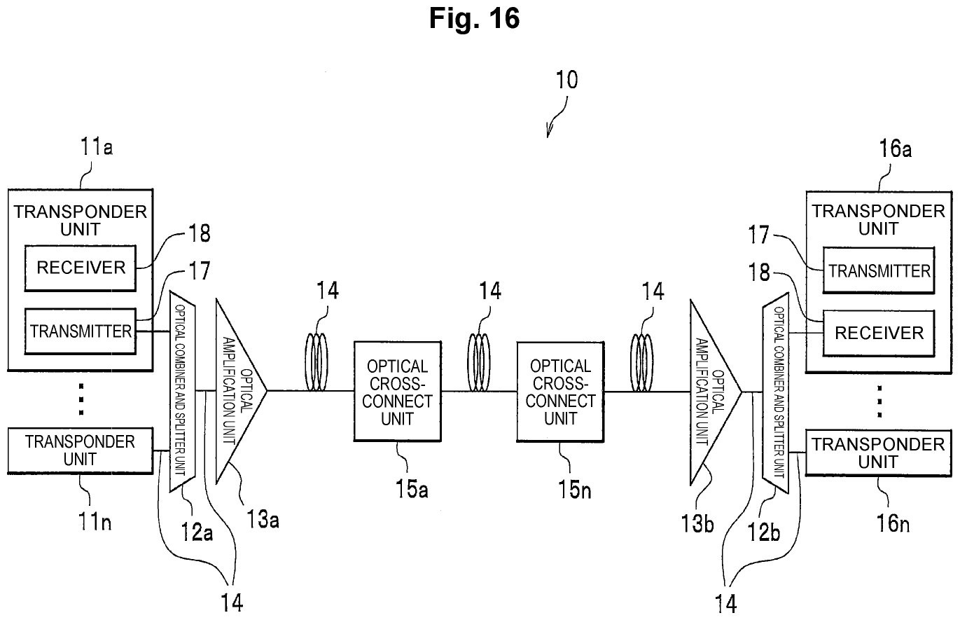

FIG. 15 is a block diagram illustrating a configuration of an optical transmission system according to a third embodiment. An optical transmission system 10D illustrated in FIG. 15 is characterized in that the transmitter 17 and the receiver 18A illustrated in FIG. 8, which are provided at distant locations, are connected to each other by the optical fiber 14, and the optical amplifier 21 configured to operate with saturated output power is coupled on the receive side with respect to the receiver 18A.

The receiver 18A includes the O/E conversion device 18b, the A/D conversion device 18c including the sampling device 18f and the normalization device 18g, the digital signal processing device 18d, and the information recognition device 18e.

With this configuration, as for the optical amplifier 21 configured to operate with saturated output power, the ratio of output power to input power draws a flat curve (refer to FIG. 3); this means that when the variation in input optical power is relatively large, the variation in output optical power is small. As a result, when an instantaneous loss variation relatively greatly changes the input optical power to the optical amplifier 21, the variation in output optical power is reduced to a relatively small amount, and thus, it is possible to properly receive information represented by the optical signal 22o inputted from the optical amplifier 21 to the receiver 18.

When an instantaneous loss variation occurs, in the case in which the BER fed back by the information recognition device 18e in accordance with the parameters N and M indicates a smallest value, the minimization of instantaneous loss variation is achieved; accordingly, the normalization device 18g ends the normalization processing. In the case in which the BER does not indicate a smallest value, the parameters N and M are adjusted to minimize the BER, and as a result, the minimization of instantaneous loss variation can be achieved.

This means that, as the input optical power to the optical amplifier 21 increases, the variation in the output optical power decreases with respect to time, and thus, the average value of variation with respect to time also decreases. The relatively small average value facilitates normalization.

Since the normalization processing uses the average value, when the average value of variation with respect to time is decreased in the optical amplifier 21, it is expected that the relatively small average value facilitates the normalization processing.

As described above, since the optical amplifier 21 configured to operate with saturated output power and the normalization device 18g in the stage after the optical amplifier 21 are both provided, it is possible to further reduce instantaneous loss variation, and consequently, further decrease the BER.

<Effects>

(1) The optical amplifier 21 coupled on the receive side with respect to the receiver 18 for receiving the optical signal 22o from the transmitter 17 for optical signal through the optical transmission line (the optical fiber 14) is configured to operate with saturated output power.

With this configuration, in the optical amplifier 21 with saturated output power illustrated as a flat curve representing the ratio of output power to input power, when the variation in the input optical power is relatively large, the variation in the output optical power is small. As a result, when an instantaneous loss variation due to optical fiber touch relatively greatly changes the input optical power to the optical amplifier 21, the variation in output optical power is reduced to a relatively small amount, and thus, it is possible to properly receive information represented by the optical signal 22o inputted from the optical amplifier 21 to the receiver 18.

(2) The input-power-adjusting optical amplifier 23 is coupled on the input side with respect to the optical amplifier 21. The input-power-adjusting optical amplifier 23 is configured to increase input optical power to the optical amplifier 21.

With this configuration, the input-power-adjusting optical amplifier 23 previously increases the power of the optical signal 22i to be outputted by the optical amplifier 23 and inputted to the optical amplifier 21 in the subsequent stage. By increasing the power of the optical signal 22i, the optical amplifier 21 can operate in an amplification area of a flatter curve (FIG. 3), and as a result, it is possible to suppress and further reduce instantaneous loss variation.

(3) The pump current of the optical amplifier 21 is decreased in amount.

With this configuration, when the amount of pump current of the optical amplifier 21 is decreased, the variation in output optical power is decreased in comparison to the case of a larger amount of pump current, and as a result, it is possible to reduce instantaneous loss variation.

(4) As for the optical amplifier 21 and the input-power-adjusting optical amplifier 23 according to (2), when the optical amplifier 21 as one of the amplifiers is implemented as an EDFA, the optical amplifier 23 as the other of the amplifiers is implemented as an SOA; or when the optical amplifier 21 as the one of the amplifiers is implemented as an SOA, the optical amplifier 23 as the other of the amplifiers is implemented as an EDFA.

With this configuration, when the optical amplifier 21 or the input-power-adjusting optical amplifier 23 is implemented as an SOA, since the saturated output power of SOA is smaller than the saturated output power of EDFA, the SOA indicates a characteristic in which the output optical power draws a flat curve in the area with small input optical power. This means that implementing the optical amplifier 21 or the input-power-adjusting optical amplifier 23 as the SOA can reduce instantaneous loss variation with the use of the characteristic in which the output optical power draws a flat curve when the input optical power is relatively small (refer to FIG. 3).

(5) The receiver 18A includes the O/E conversion device 18b, the A/D conversion device 18c, the digital signal processing device 18d, and the information recognition device 18e. The O/E conversion device 18b receives an optical signal transmitted by the transmitter 17 for optical signal through the optical transmission line and convert the optical signal into an analog electrical signal by demodulating the optical signal. The A/D conversion device 18c converts the electrical signal into a digital signal. The digital signal processing device 18d performs digital signal processing including polarization split of the digital signal, compensation for polarization/wavelength dispersion of the digital signal, compensation for waveform distortion of the digital signal, and compensation for frequency/phase offset of the digital signal. The information recognition device 18e recognizes information of “0” or “1” from the signal subjected to the digital signal processing. The A/D conversion device 18c includes the sampling device 18f and the normalization device 18g. The sampling device 18f performs sampling by sectioning the electrical signal converted by the O/E conversion device 18b at fixed time intervals and read values from the sectioned electrical signal. The normalization device 18g normalizes values of M pieces of an electrical signal corresponding to received optical power received through the optical transmission line by dividing each value by an average value of samples obtained in the sampling by sectioning an electrical signal corresponding to received optical power in accordance with the cycle period of a length of N. When the BER calculated by using the information of “0” or “1” obtained by the information recognition device 18e in accordance with normalization does not indicate a smallest value, the normalization device 18g changes both N and M (the parameters N and M) to values that minimize the BER or either N or M to a value that minimizes the BER.

With this configuration, when an instantaneous loss variation occurs, in the case in which the BER fed back by the information recognition device 18e in accordance with the parameters N and M indicates a smallest value, the minimization of instantaneous loss variation is achieved; accordingly, the normalization device 18g ends the normalization processing. In the case in which the BER does not indicate a smallest value, the parameters N and M are adjusted to minimize the BER, and as a result, the minimization of instantaneous loss variation can be achieved.

(6) In the optical transmission system 10A or 10B, the optical amplifier 21 according to (1) or (3) coupled on the receive side with respect to the receiver 18 for optical signal coupled to the transmitter 17 for optical signal via the optical transmission line; or the optical amplifier 21 and the input-power-adjusting optical amplifier 23 according to (2) or (4) coupled on the receive side with respect to the receiver for optical signal coupled to the transmitter for optical signal via the optical transmission line.

With this configuration, in the case of the optical transmission system 10A (FIG. 1) in which the optical amplifier 21 is coupled on the receive side with respect to the receiver 18, since the optical amplifier 21 operates with saturated output power, when an instantaneous loss variation changes input optical power, the variation in output optical power is reduced. In the case of the optical transmission system 10B (FIG. 6) in which the amplifier 21 and the input-power-adjusting optical amplifier 23 are coupled on the receive side with respect to the receiver 18, since the input-power-adjusting optical amplifier 23 previously increases input optical power to the optical amplifier 21, the instantaneous loss variation in the optical amplifier 21 can be further reduced.

(7) The optical transmission system 10D includes the receiver 18 according to claim 5 coupled to the transmitter 17 for optical signal via the optical transmission line and also includes the optical amplifier 21 coupled on the receive side with respect to the receiver 18 and configured to operate with saturated output power.

With this configuration, since the optical amplifier 21 configured to operate with saturated output power and the normalization device 18g in the stage after the optical amplifier 21 are both provided, it is possible to further reduce instantaneous loss variation, and consequently, further decrease the BER.

(8) The optical amplifier design method is implemented by the optical amplifier design device for designing the optical amplifier 21 configured to be coupled on the receive side with respect to the receiver 18 for receiving an optical signal from the transmitter 17 for optical signal through an optical transmission line and configured to operate with saturated output power. In the optical amplifier design method, the optical amplifier design device 30 performs a step of measuring input optical power of an optical signal inputted to the optical amplifier 21, a step of configuring in the configuration unit 32 the estimated reduction amount of the input optical power due to an instantaneous loss variation caused by a change in the bend loss of the optical fiber 14 constituting the optical transmission line, a step of calculating the variation amount of output optical power corresponding to the configured estimated reduction amount, a step of converting the calculated variation amount of output optical power into a BER according to a receive optical signal received by the receiver 18, and a step of, when the converted BER exceeds a predetermined BER expectation value, changing parameters, notably a parameter regarding material of the optical amplifier and a parameter regarding size of the optical amplifier.

With this method, the optical amplifier 21 with saturated output power, which can suppress and reduce the variation in output optical power when an instantaneous loss variation changes input optical power to the optical amplifier 21, can be designed by following the order of the processing operations in the steps described above. By using this design procedure, the optical amplifier 21 configured to operate with saturated output power can be produced to reduce instantaneous loss variation occurred in an optical signal transmitted through the optical transmission line, and consequently, the receiver 18 can obtain correct information.

Additionally, the specific configuration can be changed as appropriate without departing from the spirit and scope of the present invention.

### REFERENCE SIGNS LIST

10A, 10B, 10C, 10D Optical transmission system
14 Optical fiber (optical transmission line)
17 Transmitter
18, 18A Receiver
18b O/E conversion device
18c A/D conversion device
18d Digital signal processing device
18e Information recognition device
18f Sampling device
18g Normalization device
21 Optical amplifier configured to operate with saturated output power
23 Input-power-adjusting optical amplifier
30 Optical amplifier design device
31 Optical power measurement unit
32 Optical power reduction amount setting unit (configuration unit)
33 Optical power variation calculation unit
34 Optical power conversion unit
35 Designed BER expectation value determination unit
36 Optical amplifier parameter alteration unit
37 Parameter display unit

1. An optical amplifier coupled on a receive side with respect to a receiver for receiving an optical signal from a transmitter for optical signal through an optical transmission line, wherein
the optical amplifier is configured to operate with saturated output power.

2. The optical amplifier according to claim 1, wherein
an input-power-adjusting optical amplifier is coupled on an input side with respect to the optical amplifier, the input-power-adjusting optical amplifier being configured to increase input optical power to the optical amplifier.

3. The optical amplifier according to claim 1, wherein
a pump current of the optical amplifier is decreased in amount.

4. The optical amplifier according to claim 2, wherein
when one of the optical amplifier and the input-power-adjusting optical amplifier is implemented as an erbium doped optical fiber amplifier (EDFA), another of the optical amplifier and the input-power-adjusting optical amplifier is implemented as a semiconductor optical amplifier (SOA), or
when the one of the optical amplifier and the input-power-adjusting optical amplifier is implemented as an SOA, the other of the optical amplifier and the input-power-adjusting optical amplifier is implemented as an EDFA.

5. A receiver comprising:
an optical/electrical (O/E) conversion device configured to receive an optical signal transmitted by a transmitter for optical signal through an optical transmission line and convert the optical signal into an analog electrical signal by demodulating the optical signal;
an analog/digital (A/D) conversion device configured to convert the electrical signal into a digital signal;
a digital signal processing device, including one or more processors, configured to perform digital signal processing including polarization split of the digital signal, compensation for polarization/wavelength dispersion of the digital signal, compensation for waveform distortion of the digital signal, and compensation for frequency/phase offset of the digital signal; and
an information recognition device, including one or more processors, configured to recognize information of “0” or “1” from the signal subjected to the digital signal processing, wherein
the A/D conversion device includes
a sampling device, including one or more processors, configured to perform sampling by sectioning the electrical signal converted by the O/E conversion device at fixed time intervals and read values from the sectioned electrical signal, and
a normalization device, including one or more processors, configured to
normalize values of M pieces of an electrical signal corresponding to received optical power received through the optical transmission line by dividing each value by an average value of samples obtained in the sampling by sectioning an electrical signal corresponding to received optical power in accordance with a cycle period of a length of N, and
when a bit error rate (BER) calculated by using the information of “0” or “1” obtained by the information recognition device in accordance with normalization does not indicate a smallest value, change both N and M to values that minimize the BER or either N or M to a value that minimizes the BER.

6. An optical transmission system comprising:
the optical amplifier according to claim 1 coupled on a receive side with respect to a receiver for optical signal coupled to a transmitter for optical signal via an optical transmission line.

7. An optical transmission system comprising: the receiver according to claim 5 coupled to the transmitter for optical signal via the optical transmission line; and
an optical amplifier coupled on a receive side with respect to the receiver and configured to operate with saturated output power.

8. An optical amplifier design method implemented by an optical amplifier design device for designing an optical amplifier configured to be coupled on a receive side with respect to a receiver for receiving an optical signal from a transmitter for optical signal through an optical transmission line, the optical amplifier being configured to operate with saturated output power, wherein
the optical amplifier design device performs
a step of measuring input optical power of an optical signal inputted to the optical amplifier,
a step of configuring in a configuration unit an estimated reduction amount of the input optical power due to an instantaneous loss variation caused by a change in bend loss of an optical fiber constituting the optical transmission line,
a step of calculating a variation amount of output optical power, the variation amount corresponding to the configured estimated reduction amount,
a step of converting the calculated variation amount of output optical power into a BER according to a receive optical signal received by the receiver, and
a step of, when the converted BER exceeds a predetermined BER expectation value, changing parameters, notably a parameter regarding material of the optical amplifier and a parameter regarding size of the optical amplifier.

9. An optical transmission system comprising:
the optical amplifier according to claim 3 coupled on a receive side with respect to a receiver for optical signal coupled to a transmitter for optical signal via an optical transmission line.

10. An optical transmission system comprising:
the optical amplifier and the input-power-adjusting optical amplifier according to claim 2 coupled on the receive side with respect to the receiver for optical signal coupled to the transmitter for optical signal via the optical transmission line.

11. An optical transmission system comprising:
the optical amplifier and the input-power-adjusting optical amplifier according to claim 4 coupled on the receive side with respect to the receiver for optical signal coupled to the transmitter for optical signal via the optical transmission line.
